(19) United States
(12) Patent Application Publication
(10) Pub. No.: US 2013/0036971 A1
(43) Pub. Date: Feb. 14, 2013

(54) LIFTING AND CONVEYING APPARATUS FOR CHEMICAL BATH DEPOSITION

(71) Applicants: PO-CHING YU, Chungli City (TW); CHUAN-YI CHEN, Chungli City (TW)

(72) Inventors: PO-CHING YU, Chungli City (TW); CHUAN-YI CHEN, Chungli City (TW)

(73) Assignee: MANZ TAIWAN LTD., Taoyuan County (TW)

(21) Appl. No.: 13/570,268

(22) Filed: Aug. 9, 2012

(30) Foreign Application Priority Data
Aug. 10, 2011 (TW) 100214845

(51) Int. Cl. B05C 3/10

(52) U.S. Cl. 118/602; 118/425

(57) ABSTRACT

An approach is provided for a lifting and conveying apparatus for chemical bath deposition (CBD). The apparatus is adapted for depositing at least one thin film on a substrate of a solar cell, and is configured for conveying a reacting container in ways of up and down and back and forth, which makes the solution evenly and fully spread on a substrate to produce a deposited thin film with a uniform thickness under a suitable reacting condition.

### FIELD OF THE INVENTION

Embodiments of the present disclosure relate to a chemical bath deposition (CBD) apparatus, especially toward a chemical bath deposition (CBD) apparatus for conveying a reacting container in ways of up and down and back and forth, which makes solution well and even spread on a substrate to produce a thin film with a uniform thickness.

### BACKGROUND

With rapidly development of electronic industry, a physical or chemical deposition technique is more commonly used in producing a lot of kinds of electronic devices/equipments. At the same time, requirements of solar cells or hydrogen fuel cells are broadly increased due to petroleum exhaustion, highly expense and environment protection issues. While manufacturing a solar cell, the physical or chemical deposition technique also is widely applied in forming at least one deposition layer (film) on a substrate to make the solar cell available. Therefore, the deposition technique obviously is a core technique used in the electronic industry and commodity industry.

The chemical bath deposition (CBD) method and an associated apparatus, one of a common deposition technique, dispose a substrate with a pre-treated surface (i.e. a mono/poly crystalline silicon substrate or non-crystalline silicon substrate) in a chemical solution a period to form a semi conductive layer (film) on the surface of the substrate. However, the present use of the chemical bath deposition (CBD) usually immerse whole substrate in a chemical solution, deposits on both surfaces of the substrate, and thus increases manufactory expense and material waste.

With reference to FIG. 1, FIG. 1 is a schematic view of another conventional chemical bath depositing apparatus. The apparatus comprises a transmission unit 20 and a thermal bath 30. The transmission unit 20 is used to deliver a chemical solution container 40 and comprises multiple transmission wheels 201. The chemical solution container 40 is assembled by sealing a substrate 401 with a chemical solution cover 403, and is injected with a chemical solution 50 to cover the substrate 401. This apparatus is able to produce one surface of the substrate 401 being covered by the chemical solution 50.

The thermal bath 30 comprises a hot water 301, and the hot water 301 has a liquid surface 3011. The transmission wheels 201 are disposed under the liquid surface 3011 of the hot water 301. While the chemical solution container 40 is delivered by the transmission wheels 201, a lower portion of the chemical solution container 40 is immersed in the thermal bath 301. The chemical solution 40 is then heated by the hot water 301 for the reaction of the chemical deposition.

However, the above-mentioned deposition has a drawback of having a non-uniform thickness of the deposited film, because the chemical solution cannot spread evenly on the substrate when injecting the chemical solution into the solution container. Increasing the amount of the injected chemical solution may help the spread on the substrate, but too much injected chemical solution may deform or damage the substrate.

Therefore, there is a need for an approach to provide a device or mean for chemical bath deposition (CBD) that is able to make the solution well and even spread on the substrate without increasing the amount of the chemical solution to produce a thin film with a uniform thickness.

### SOME EXEMPLARY EMBODIMENTS

These and other needs are addressed by the present disclosure, wherein an approach is provided for a lifting and conveying apparatus for chemical bath deposition (CBD) that conveys a reacting container in ways of up and down and back and forth, which makes solution well and even spread on a substrate to produce a deposited thin film with a uniform thickness under a optima reacting condition.

Another approach is provided for a lifting and conveying apparatus for chemical bath deposition (CBD) that is able to provide more stable chemical reacting temperature and environment with mechanisms of heat preservation and control using thermal insulated materials or a circulatory heating system. The stable chemical reacting temperature and environment is benefit to the process of thin film deposition.

According to one aspect of an embodiment of the present disclosure, a lifting and conveying apparatus for chemical bath deposition (CBD) at least comprises a conveying module and a bath. The conveying module is configured for conveying a reacting container, and is assembled at least with multiple rollers inside the bath. The reacting container is at least assembled with a reacting cover sealed on a substrate. The substrate has an upper surface, and a solution is introduced to the reacting container for covering the upper surface of the substrate. The rollers are able to move in ways of up and down and back and forth. Therefore, the solution is fully spread on the upper surface of the substrate, as the reacting container on the rollers descending in the liquid and then moving back and forth. The thin film grows even and completely on the upper surface consequently.

Accordingly, by immersing and moving the reacting container in the liquid back and forth, this will make the solution spreading to every portion of the substrate that produces better unity of the deposition of the film.

### BRIEF DESCRIPTION OF THE DRAWINGS

The disclosure is illustrated by way of example, and not by way of limitation, in the figures of the accompanying drawings in which like reference numerals refer to similar elements and in which:

FIG. 1 is a schematic view of a conventional chemical bath depositing apparatus;

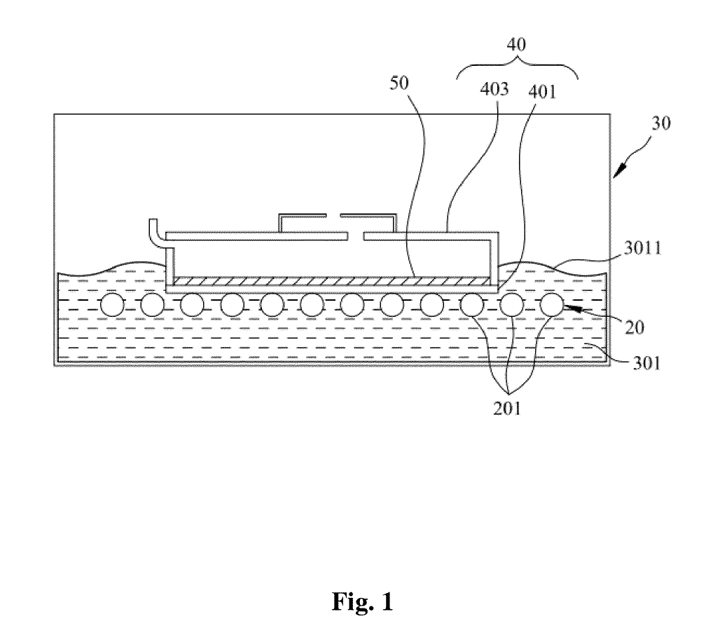

FIG. 2 is an exemplary diagram of a lifting and conveying apparatus for chemical bath deposition (CBD) that conveys the reacting container in accordance with an embodiment of the present disclosure;

FIG. 3A is an exemplary diagram illustrated the lifting module of the lifting and conveying apparatus for chemical bath deposition (CBD) in accordance with an embodiment of the present disclosure;

FIG. 3B is an exemplary diagram illustrated the reacting container of FIG. 3A being leaded into the liquid with the conveying module;

FIG. 4 is an exemplary diagram illustrated a reacting container moving back and forth with the rollers in accordance with another embodiment of the present disclosure; and

FIG. 5 is an exemplary diagram illustrated a lifting and conveying apparatus for chemical bath deposition (CBD) with a circulatory heating system in accordance with an embodiment of the present disclosure.

### DESCRIPTION OF THE PREFERRED EMBODIMENT

Embodiments of the apparatus and/or methods are disclosed. In the following description, for purposes of explanation, numerous specific details are set forth in order to provide a thorough understanding of the embodiments of the disclosure. It is apparent, however, to one skilled in the art that the present disclosure may be practiced without these specific details or with an equivalent arrangement.

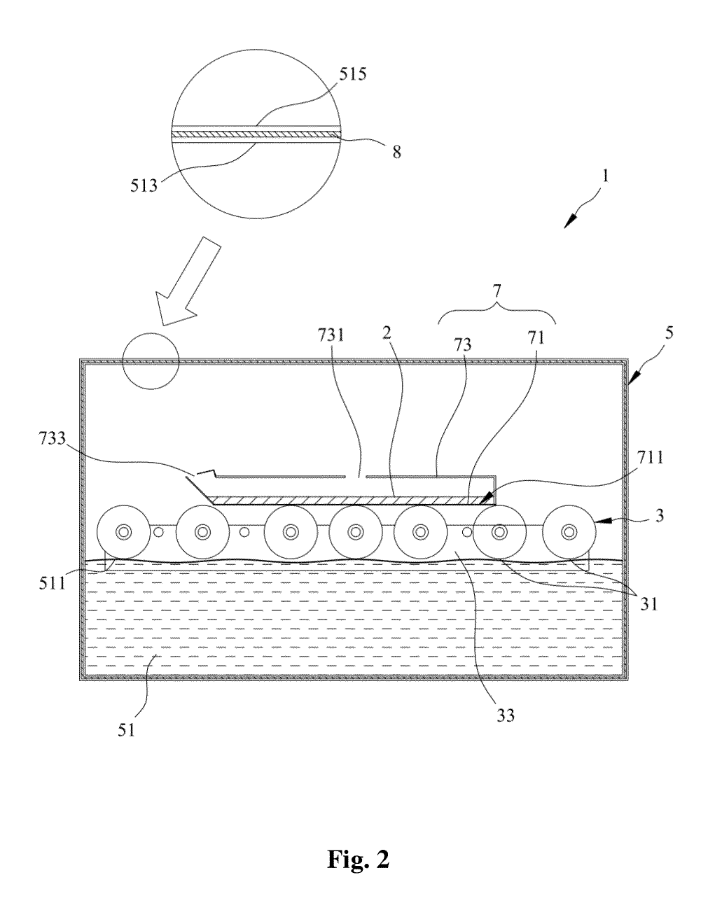

With reference to FIG. 2, FIG. 2 is an exemplary diagram of a lifting and conveying apparatus for chemical bath deposition (CBD) that conveys the reacting container in accordance with an embodiment of the present disclosure. In this embodiment, the apparatus 1 may be used in a process of depositing at least one thin film on a substrate of a solar cell, which conveys the substrate in ways of up and down and back and forth that makes solution well and fully spread on the substrate. A thin film is then able to grow completely and evenly on the substrate, and thus the unity of the thickness of the thin film is improved.

As shown in FIG. 2, the lifting and conveying apparatus for chemical bath deposition (CBD) at least comprises a conveying module 3 and a bath 5. The conveying module 3 is configured for conveying a reacting container 7, and is assembled at least with multiple rollers 31. The multiple rollers 31 are disposed horizontally and aligned to each other. The reacting container 7 is at least assembled with a reacting cover 73 sealed on a substrate 71. In order to avoid obscuring the embodiment, some well-known components are not illustrated or described, for instance, although the reacting cover 73 may have some other minor components been omitted, it will not be a problem for those skilled in the art to understand the present disclosure hereinafter.

The reacting cover 73 shelters on an upper surface 711 of the substrate 71, and at least comprises an inlet 731 and an outlet 732. In this manner, a solution 2 is introduced into the reacting container 7 through the inlet 731 for wearing on the upper surface 711 of the substrate 71. The outlet 732 is defined as an exit, and is configured for the solution 2 to be drained to the exterior of the reacting container 7. It is noted that reacting container 7 is only an embodiment for describe the present disclosure in ease. The term “reacting container 7” should not used as limitations of the present disclosure, and it is apparent, any structure is capable of sealing with the substrate can be treated as an equivalent arrangement.

The bath 5 may be a sealed box containing a liquid. The liquid, in this embodiment, may be a liquid 51 with a temperature higher than the room temperature. However, the temperature of the liquid 51 can also be lower than the room temperature in response to the desire of the corresponding manufacturing process. The rollers 31 are located inside the bath 5, and are alternatively placed above or under a surface 511 of the liquid 51. In this embodiment, as shown in FIG. 2, the rollers 31 are originally placed above the surface 511 of the liquid 51. The bath 5 comprises an inner surface 513 and an outer surface 515, and may further comprise a thermal insulated material 8 disposed between the inner surface 513 and the outer surface 515. The thermal insulated material 8 is adapted for preventing the temperature of the liquid 51 has drastic changes. Alternatively, the bath 5 may further comprises a heater or a cooler (not shown) disposed between the inner surface 513 and the outer surface 515 for adjusting the temperature of the bath 5.

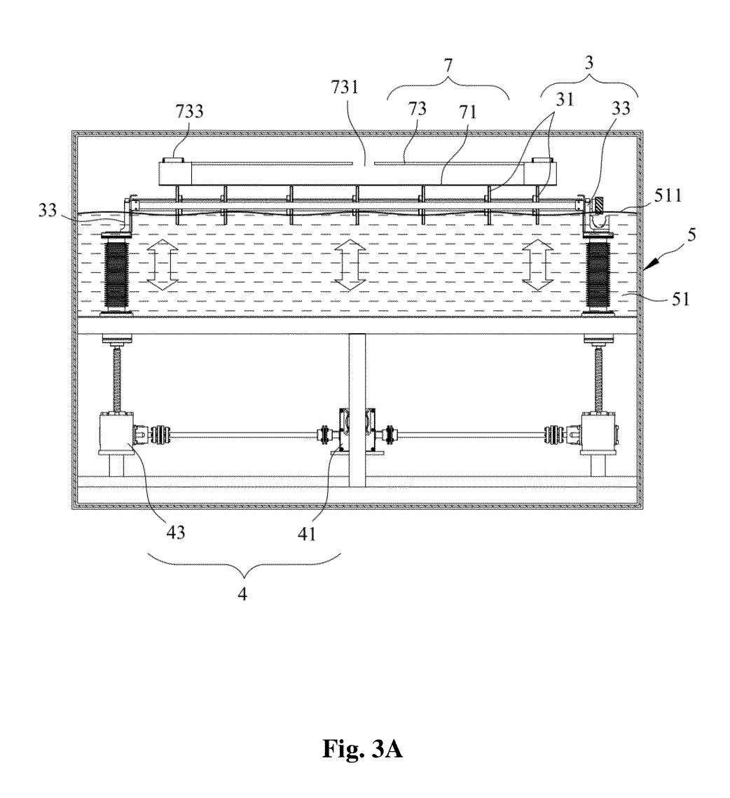

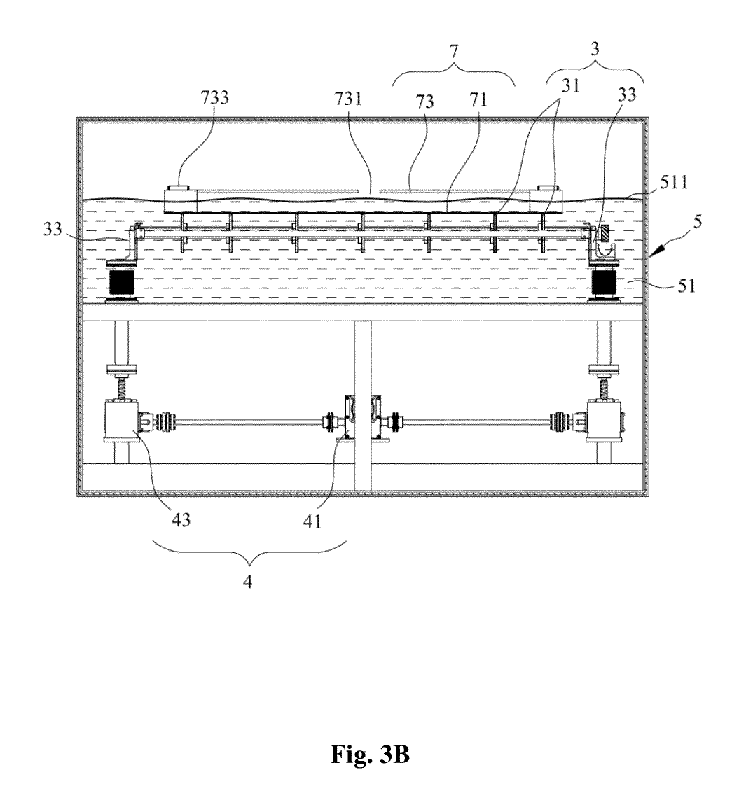

With reference to FIGS. 3A and 3B, FIG. 3A is an exemplary diagram illustrated the lifting module of the lifting and conveying apparatus for chemical bath deposition (CBD) in accordance with an embodiment of the present disclosure. FIG. 3B is an exemplary diagram illustrated the reacting container 7 being leaded into the liquid 51 with the conveying module 3. In this embodiment, the conveying module 3 can be vertically lifted up and down, which moves the reacting container 7 in or out from the liquid 51. However, as shown in FIG. 3B, in order to avoid the liquid 51 flowing into the reacting container 7, As the reacting container 7 is leaded into the liquid 51 with the conveying module 3, the minimum heights of the inlet 731 and the outlet 733 of the reacting container 7 is limited to a value higher than the height of the surface 511 of the liquid 51. The reason behind making the heights of the inlet 731 and the outlet 733 of the reacting container 7 higher than the surface 511 of the liquid 51, the solution 2 may be one of the reagent being capable of reacting with the substrate 71, and the liquid 51 in the bath 5 may consider as an media that helps the chemical reactions of the solution and the substrate 71, and liquid 51 itself does not involve any reaction for deposition.

As shown in FIG. 3B and further reference to FIG. 2, when the reacting container 7 is leaded in to the liquid 51, the solution 2 is only apart from the liquid 51 separated by the substrate 71. The solution 2 is able to receive heat from the liquid 51 underneath the substrate 71 to produce a stable chemical reaction for film deposition.

In this embodiment, a lifting module 4 is mounted under the conveying module 3, and the up and down of the conveying module 3 is controlled by the lifting module 4. The lifting module 4 is able to drive the conveying module 3 in a direction of a vertical direction or a diagonally direction. When the lifting module 4 is descended, the lifting module 4 immerses at least the substrate 71 above the rollers 31 in the solution 51.

In this embodiment, as shown in FIGS. 3A and 3B, the rollers 31 are mounted between two corresponding support stands 33, the lifting module 4 at least comprises a motor 41 and at least two ball screws 43. The two ball screws 43 are mounted at a lower portion of the two support stands 33 respectively, which supports the support stands 33 in a horizontal state. As above mentioned, the previous described structure of the lifting module 4 and illustrated in the drawings are only for the purposes of explaining the features of the present disclosure, some omitted well-known components will not be a problem for those skilled in the art to understand the present disclosure hereinafter.

The motor 41 is configured for simultaneously driving the at least two ball screws 43 up or down that makes the two support stands 33 move up or down in a linear relation. As the two support stands 33 move up or down, the rollers 31 and the reacting container 7 will follow and are leaded by the two support stands 33. It achieves the purpose of making the reacting container 7 moving in ways of up and down to the solution 51. It is noted that the structure of the motor and the ball screws previous described is only for the purpose of describing the embodiment illustrated in the drawings. The lifting module can be a different structure, not limited to the above embodiments, that is able to make the reacting container up and down.

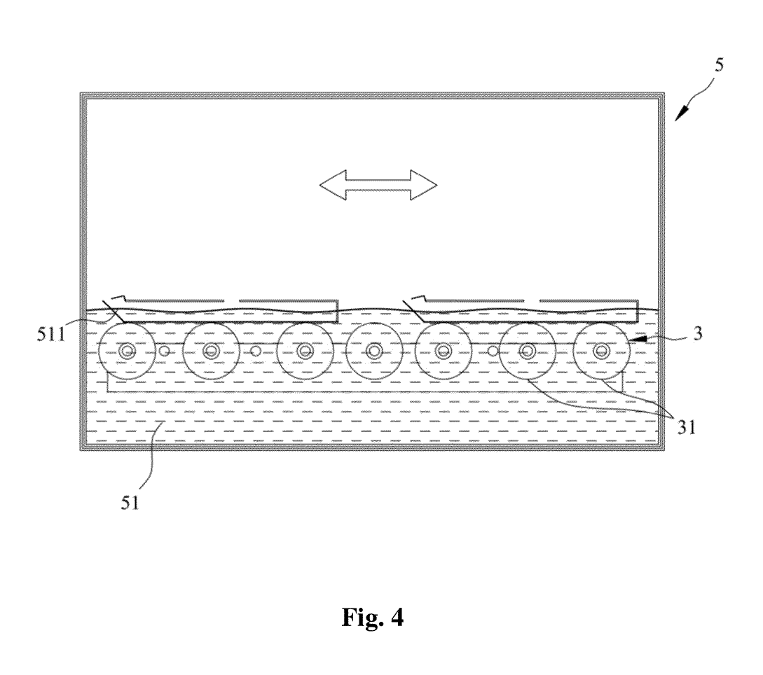

With reference to FIGS. 2 and 4, FIG. 4 is an exemplary diagram illustrated a reacting container 7 moving back and forth with the rollers 31. In order to make the solution 2 fully spread on the upper surface 711 of the substrate 71, the rollers 31 alternatively move the reacting container 7 back and forth. In one embodiment, the reacting container 7 is start moving back and forth as the rollers 31 rolling forward and backward by turns after the reacting container 7 is immersed in the solution 51. The solution 2 is then spread to every portion on the upper surface 711 of the substrate 71, and especially for the edges of the upper surface 711 that are completely immersed in the solution 2. Accordingly, the difference of the thin film thickness among the center and edges on the substrate 71 can be reduced.

Since the solution 2 is able to completely spread on the upper surface 711 of the substrate 71, it sustains the substrate 71 with an adequate reacting time to every portion on the upper surface 711 for thin film deposition, which unifies the thickness of the thin film deposited on the substrate 71. In addition, the thin film deposited on substrate 71 with a uniform thickness that benefits the successive manufacturing processes.

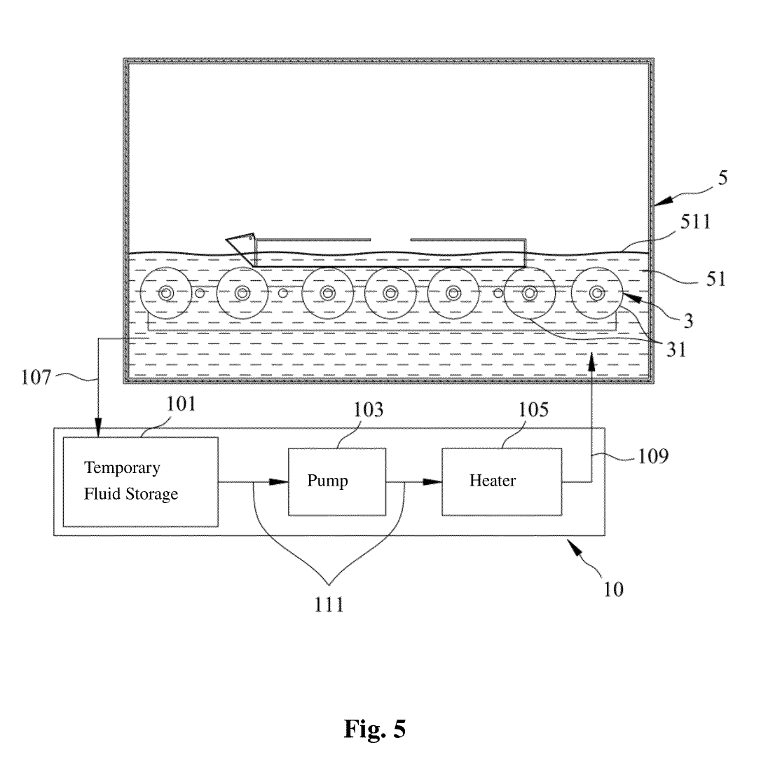

With reference to FIG. 5, FIG. 5 is an exemplary diagram illustrated another embodiment of a lifting and conveying apparatus for chemical bath deposition (CBD) with a circulatory heating system. In this embodiment, the lifting and conveying apparatus for chemical bath deposition (CBD) further comprises a circulatory heating system 10. The circulatory heating system 10 at least comprises a temporary fluid storage 101, a pump 103 and a heater 105. The temporary fluid storage 101 is connected to the bath 5 through at least one recycling pipe 107. One end of the recycling pipe 107 is placed in the liquid 51. The pump 103 is connected to the fluid storage 101 and the heater 105 through a pipe 11 respectively. The heater 105 is connected to the bath 5 through at least one distributing pipe 109, and one end of the distributing pipe 109 is alternatively placed inside or above the liquid 51.

In this arrangement, the liquid 51 in the bath 5 may flow to the temporary fluid storage 101, and then flow to the pump 103 and the heater 105 through the pipes 111. The pump 103 is configured to providing a pressure to convey the liquid 51 to the heater 105. The heater 105 heats up the liquid 51 that is flowed to the heater 105. Due to the force of the pressure generated by the pump 103, the heated liquid 51 in the heater 105 will send back to the bath 5 through the distributing pipe 109.

Accordingly, the liquid 51 in the bath 5 will flow to the circulatory heating system 10 first, and then flow the heated liquid 51 back to the bath 5 through the distributing pipe 109 by the pump 103 and the heater 105. The temperature of the liquid 51 in the bath 5 can be constant, as the bath 5 continuously receiving the heated liquid 51. The chemical reaction of the thin film to the solution 2 is able to react in a stable temperature of the environment.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A lifting and conveying apparatus for chemical bath deposition (CBD), comprising:
a bath being configured for containing a liquid;
a conveying module being assembled with at least multiple rollers inside the bath, and being configured for conveying a reacting container formed at least with a substrate, wherein the rollers rolls forward and backward by turns, which conveys the reacting container back and forth; and
a lifting module being mounted under the conveying module, and being configured for making the conveying module to move up and down.

2. The lifting and conveying apparatus as claimed in claim 1, wherein the lifting module moves the conveying module in a direction of a vertical direction or a diagonally direction.

3. The lifting and conveying apparatus as claimed in claim 2, wherein at least the substrate is immersed in the liquid, when the lifting module descends.

4. The lifting and conveying apparatus as claimed in claim 1, wherein at least the substrate is immersed in the liquid, when the lifting module descends.

5. The lifting and conveying apparatus as claimed in claim 1, further comprising a thermal insulated material disposed between an inner surface and an outer surface of the bath.

6. The lifting and conveying apparatus as claimed in claim 1, further comprising a heater or a cooler disposed between an inner surface and an outer surface of the bath, which modulates the temperatures of the bath and the liquid.

7. The lifting and conveying apparatus as claimed in claim 1, further comprising a circulatory heating system, and the circulatory heating system comprising:
a temporary fluid storage being connected to the bath through at least one recycling pipe;
a pump being connected to the temporary fluid storage through a pipe, and being configured for providing a pressure to convey the liquid; and
a heater being connected to the pump through a pipe, and being connected to the bath through at least one recycling pipe, wherein the heater heats the liquid that is passed through the heater and the heated liquid returns to the bath by the pressure of the pump.

8. The lifting and conveying apparatus as claimed in claim 7, wherein an end of the recycling pipe is placed in the liquid, and one end of the distributing pipe is alternatively placed inside or above the liquid.

9. The lifting and conveying apparatus as claimed in claim 1, wherein
the conveying module further comprises two support stands, and the rollers are mounted corresponding between the two support stands; and
the lifting module at least comprises a motor and two ball screws, the two ball screws are respectively mounted at a lower portion of the two support stands, and the two support stands and rolls are simultaneously move up or down whereby the motor drives the two ball screws up or down simultaneously.
